(19) United States
(12) Patent Application Publication
(10) Pub. No.: US 2010/0203454 A1
(43) Pub. Date: Aug. 12, 2010

(54) ENHANCED TRANSPARENT CONDUCTIVE OXIDES

(76) Inventors: Mark Brongersma, Redwood City, CA (US); Anthony Defries, Los Angeles, CA (US)

Correspondence Address: MATTER, INC., 149 S. BARRINGTON AVE #757, LOS ANGELES, CA, 90049, US

(21) Appl. No.: 12/703,646

(22) Filed: Feb. 10, 2010

Related U.S. Application Data
(60) Provisional application No. 61/151,329, filed on Feb. 10, 2009.

(51) Int. Cl. H01B 1/08; C09K 5/00; B05D 5/12; C23C 14/34; G03F 7/20

(52) U.S. Cl. 430/311; 252/518.1; 252/71; 427/126.3; 204/192.15

(57) ABSTRACT

A method of engineering of enhanced transparent conducting oxides by incorporating discrete metallic particles and structures, nonmetallic, organic and inorganic metamaterials or nanostructures in order to manipulate optical, thermal, electronic or electrical energy, properties or effects. A method of using transparent conducting oxides (TCO) incorporating discrete metallic particles and structures, nonmetallic, organic or inorganic metamaterials or nanostructures for any purpose including to manipulate optical, thermal, electronic or electrical energy, properties or effects in or on any material, substrate, or device.

### CROSS REFERENCE TO RELATED APPLICATIONS

This application claims benefit of and priority to U.S. Provisional Patent Application No. 61/151,329 filed Feb. 10, 2009 entitled “Plasmonic Transparent Conductive Oxides”.

References Cited: U.S. Patent Documents:

| | | |
|---|---|---|
| 7,088,449 | August 2006 | Brongersma |
| 6,441,945 | August 2002 | Atwater, et al. |
| 7,504,136 | March 2009 | Boyd, et al. |

### OTHER REFERENCES

M. L. Brongersma. “Plasmonics: Engineering optical nanoantennas.” Nature Photonics, May 2008.
M. L. Brongersma. “Nanoshells: gifts in a gold wrapper.” Nature Materials, Vol. 2. May 2003.
M. A. Green, et al. “Surface plasmon enhanced silicon solar cells.” Journal of Applied Physics 101, 093105, May 2007.
P. Cheng, et al. “Enhancement of ZnO light emission via coupling with localized surface plasmon of Ag island film.” American Institute of Physics, January 2008.
K. R. Catchpole et al. “Plasmonic solar cells.” Optics Express. Vol. 16, No. 26. December 2008.
D. Derkacs et al. “Improved performance of amorphous silicon solar cells via scattering from surface Plasmon polaritons in nearby metallic nanopaticles.” Applied Physics Letters, 89, 093103, August 2006.
M. L. Brongersma and Peter G. Kik. Surface Plasmon Nanophotonics. Dordrecht, The Netherlands: Springer 2007.
U. Kreibig and M. Vollmer. Optical Properties of Metal Clusters. New York: Springer: 1995.
S. Maier. Plasmonics: Fundamentals and Applications. New York: Springer: 2007.

### BACKGROUND

1. Field

This invention concerns the engineering of enhanced transparent conducting oxides by incorporating discrete metallic particles and structures, nonmetallic, organic and inorganic metamaterials or nanostructures in order to manipulate optical, thermal, electronic or electrical energy, properties or effects. This invention also concerns the use of transparent conducting oxides (TCO) incorporating discrete metallic particles and structures, nonmetallic, organic or inorganic metamaterials or nanostructures for any purpose including to manipulate optical, thermal, electronic or electrical energy, properties or effects in or on any material, substrate, or device. TCO, such as ITO, ZnO, In₂O₃, SnO₂In and others, perform critical management functions in a variety of technologies for which large area electronic and optical access is required. They offer electrical conductivity and optical transparency in the visible and near IR ranges of the electromagnetic spectrum. Metallic and other nanostructures can improve upon these properties by reason of their superior optical, electrical, electronic and thermal properties and their ability to induce strong-light matter interactions. In some cases completely new functionalities may be obtained. Discrete metallic nanostructures may be introduced or embedded in the TCO layer to optimize the optical, thermal, electronic and electrical behavior and properties of micro or nanostructured materials, atomic layer structures and localized surface plasmons through light manipulation, photocurrent or photocatalysis reactions, wavelength and wavelength frequency management and localized or surface plasmon resonance in any material or device. Optimizing or changing such properties would alter the behavior of the TCO. Incorporation of sub-wavelength metallic nanostructures in TCO can result in the formation of an effective medium with an increased average carrier density, shifting its plasma frequency and changing the wavelength/color where the TCO becomes transparent. Sub-wavelength particles can also be used to control absorption and scattering at desired wavelengths related to or dependent on the localized or surface plasmon resonance of a specific particle. Larger particles can be used to engineer various optical effects including absorption, scattering, light trapping or detrapping, filtering, light induced heating and others. When particles of a sufficiently large size are incorporated in a TCO layer it no longer behaves as an effective medium with a higher charge concentration, allowing strong reflection at longer wavelengths to be avoided. The control of physical features or morphology of particles including size, shape, density, uniformity, conformity, separation, placement and random or periodic distribution can be used to influence these effects. Placing particles in regular, periodic, aperiodic or random arrays further increases the possibilities for light manipulation. Many optical devices, including solar cells, solid state light emitters and flat panel displays can benefit from such functionalities. The metallic nanostructures can form a connected network or be physically separated by the host TCO matrix. In both cases the metals can improve the electrical conductivity of the composite material due to wavelength frequency resonance. Connected metal networks and disconnected particles exhibit very different optical properties allowing for the potential to individually tailor the electronic and optical properties of these films. The high electrical and thermal conductivity of metals can also increase the electrical and thermal transport through TCO films containing metallic nanostructures allowing these enhanced TCO films to perform simultaneous electrical, thermal, and optical functions. More specific benefits and properties can be obtained in the manner described by various suggested embodiments contained in this application.

2. Related Art

TCO are traditionally deployed as continuous thin film metal oxides with specific light transparency and electrical conductivity properties. It has been desirable to preserve and enhance or extend these properties, particularly transparency. The introduction of additional discrete metallic structures has not previously been suggested in TCO development. Exploiting the ability of metallic nanostructures to shift the transparency window of TCO or to enable enhanced optical, thermal, electrical or electronic management functions has not been suggested. The apparent contradiction or incompatibility of adding reflective, non-transparent metallic structures to TCO would render such a course of action non-obvious. TCO typically posses a high transparency in the 0.4 mm to 1.5 μm range. Useful electrical conductivities in excess of 10³ Ω⁻¹cm⁻¹ can be obtained through electrical doping to degeneracy. There is strong absorption on the short wavelength side due to optical transition across the band gap of the oxide. At long wavelengths the TCO behaves like a nearly free electron metal due to electrical doping. For this reason it becomes highly reflective similar to a real metal. Transition from the transparent to reflective regime occurs at a frequency called the plasma frequency. This frequency scales with the square root of the carrier density. This frequency is typically in the deep UV for real metals resulting in their mirror-like appearance at longer wavelengths (e.g. the visible). Since electrical doping of the TCO can only give rise to relatively low carrier density (10¹⁹-10²¹ cm⁻³) compared to real metals (10²³-10²⁴ cm⁻³) TCO are transparent in the visible and near IR.

Markets and applications for TCO are growing rapidly. One of the key uses is in architectural glass and heat efficient windows for which purpose tens of thousands of square kilometers are produced every year. In this application the high reflectivity of TCO at long wavelengths is exploited to keep buildings cool while allowing visible light entry. The largest TCO market is flat-panel displays. These are used in computers, monitors, displays, cameras, consumer electronics, information technology, television and video, electronic billboards, video games, media players, PDA and mobile phones. Another major field of applications is derived from the need to protect or shield many optical, electrical, electronic and mechanical devices from electromagnetic interference (EMI) and electromagnetic frequencies (EMF). TCO play an important role in this field where their use includes the aerospace, automotive, communications, solar, lighting, media, transportation, information technologies, medical, health, electronics, semiconductors and many other industries. Enhanced TCO would embrace applications in sectors as diverse as advertising, aerospace, automotive, biotechnology, chemical processing, communications, consumer electronics, construction, ecological, electrical engineering, energy, environmental, fabrics and textiles, industrial processing, information technology, insulation, lighting, marketing, mechanical engineering, media, medical, military, mining, optoelectronics, pharmaceutical, resource management, security, transportation, water and waste treatment.

### DESCRIPTION OF THE INVENTION

This invention concerns the engineering of enhanced transparent conducting oxides by incorporating discrete metallic particles and structures, nonmetallic, organic and inorganic metamaterials or nanostructures in order to manipulate optical, thermal, electronic or electrical energy, properties or effects. This invention also concerns the use of transparent conducting oxides (TCO) incorporating discrete metallic particles and structures, nonmetallic, organic or inorganic metamaterials or nanostructures for any purpose including to manipulate optical, thermal, electronic or electrical energy, properties or effects in or on any material, substrate, or device. TCO, such as ITO, ZnO, In₂O₃, SnO₂In and others perform critical management functions in a variety of technologies for which large area electronic and optical access is required. They offer electrical conductivity and optical transparency in the visible and near IR ranges of the electromagnetic spectrum. Metallic and other nanostructures can improve upon these properties by reason of their superior optical, electrical, electronic and thermal properties and the ability to induce strong light matter interactions. In some cases completely new functionalities may be obtained. Discrete metallic nanostructures may be introduced or embedded in the TCO layer to optimize the optical, thermal, electronic and electrical behavior and properties of micro or nanostructured materials, atomic layer structures and localized surface plasmons through light manipulation, photocurrent or photocatalysis reactions, wavelength and wavelength frequency management and localized or surface plasmon resonance in any material or device. Optimizing or changing such properties would alter the behavior of the TCO. Incorporation of sub-wavelength metallic nanostructures in TCO can result in the formation of an effective medium with an increased average carrier density, shifting its plasma frequency and changing the wavelength/color where the TCO becomes transparent. Sub-wavelength particles can also be used to control absorption and scattering at desired wavelengths related to or dependent on the localized or surface plasmon resonance of a specific particle. Larger particles can be used to engineer various optical effects including absorption, scattering, light trapping or detrapping, filtering, light induced heating and others. When particles of a sufficiently large size are incorporated in a TCO layer it no longer behaves as an effective medium with a higher charge concentration, allowing strong reflection at longer wavelengths to be avoided. The control of physical features or morphology of particles including size, shape, density, uniformity, conformity, separation, placement and random or periodic distribution can be used to influence these effects. Placing particles in regular, periodic, aperiodic or random arrays further increases the possibilities for light manipulation. Many optical devices, including solar cells, solid state light emitters and flat panel displays can benefit from such functionalities. The metallic nanostructures can form a connected network or be physically separated by the host TCO matrix. In both cases the metals can improve the electrical conductivity of the composite material due to wavelength frequency resonance. Connected metal networks and disconnected particles exhibit very different optical properties allowing for the potential to individually tailor the electronic and optical properties of these films. The high electrical and thermal conductivity of metals can also increase the electrical and thermal transport through TCO films containing metallic nanostructures allowing these enhanced TCO films to perform simultaneous electrical, thermal, and optical functions. More specific benefits and properties can be obtained in the manner described by various suggested embodiments contained in this application.

In an exemplary embodiment of the invention described herein, introducing separated or connected metallic particles into TCO coatings can increase electrical conductivity. High conductivity metals can be introduced into the TCO in the form of nanoparticles, nanowires, branched nanostructures, or micron scale metallic structures. This could be accomplished by, deposition of a first TCO layer, deposition or inclusion of metallic or other nanostructures and deposition of a second TCO layer. The thickness and composition of the first TCO layer could be the same as or different than the thickness and composition of the second TCO layer. The metallic nanostructures could include a variety of metals or other materials in a plurality of forms and structures. Metallic or other nanostructures can improve TCO properties by reason of their superior optical, electrical, electronic and thermal properties and the ability to induce strong light matter interactions. Discrete metallic nanostructures may be introduced or embedded in the TCO layer to optimize the optical, thermal, electronic and electrical behavior and properties of micro or nanostructured materials, atomic layer structures and localized surface plasmons through light manipulation, photocurrent or photocatalysis reactions, wavelength and wavelength frequency management and localized or surface plasmon resonance in any material or device. Optimizing or changing such properties would alter the behavior of the TCO. Applications could include better charge injection or extraction from solar cells, solid-state lighting, flat-panel and other displays or specialty glass. Such an embodiment may enable thinner films with equal electrical conductivity and potentially superior optical properties. There would be benefits in the form of reduced costs and use of resources for TCO containing metals that are becoming scarce such as ITO with indium.

A feature of the invention described herein may include the development of engineering methods or tools for use in the study, design, testing or optimization of thin films, semiconductors, solar cells or similar devices, structures and materials. Such methods or tools could provide for test platforms (platforms), transducers or other devices to study or optimize the optical, electronic and electrical behavior and properties of micro or nanostructured materials, atomic layer structures and localized surface plasmons. The field of studies and effects addressed by such platforms or devices could further include or relate to light manipulation, photocurrent or photocatalysis reactions, wavelength and wavelength frequency management and localized or surface plasmon resonance in any material or device. Such tools could include test platforms described in, expressed on or integrated with a variety of materials and form factors. Examples of such materials and form factors could include: a) for electrical IO elements—printed circuit boards (PCB), integrated circuits (IC) for probe cards or other interface means, chips, microprocessors, silicon on insulator (SOI), or any semiconductor materials, including silicon, and b) for optical IO—wavelengths of any frequency may be used for transmission and detection, particularly in the range 200 nm to 900 nm or for telecom purposes wavelengths in the 1.5 um and 1.3 um ranges ICs. All may be drawn from groups II-VI and VII of the periodic table of the elements considered well known to those skilled in the art. Said materials and form factors may be drawn from and include any and all known material combinations and may further include all known dopants or dopant combinations. Said platforms may be expressed in or deposited on various forms, substrates or structures including silicon, glass, plastics, polymers, composites, laminates, metals, optical fiber, carbon nanomaterials, crystal lattice, membranes, cavities, micro-fluidic and nano-fluidic chambers and reactors or any combination of similar structures. The platform may be provided with electronic, electrical or optical surface transport interface and connection features to facilitate real time data capture, input, output, sharing and transmission functions. Connection and transmission features may include all known forms of embedded or printed circuits, pin type connectors, radio frequency (RF), Infrared (IR) transceivers or other means of transmission. In an exemplary embodiment, a platform expressed as a printed circuit board (PCB) can be provided or used as an engineering tool for thin film design and testing. Such a PCB platform can be used to design and test thin films, including transparent conductive oxides (TCOs) and TCOs enhanced with metallic nanostructures or metamaterials. The PCB platform described herein may capture or accept data and any other form of direct or indirect external stimulus. The platform is accessible to measuring and diagnostic devices including computers. The platform is a real-time device through which data can be shared or exchanged with computers and measuring or diagnostic devices in various forms for a broad range of tasks and objectives including analysis, interpretation, metrology, testing, simulation and design. The platform could be implemented or deployed by placing it on a sample of any material or device for the purpose of optimization, testing or design. Alternatively, the platform may be integrated directly with any material or device.

In an exemplary embodiment, a PCB platform can be built using a SOI wafer as the substrate. The dimensions of the SOI wafer could be 10 cm square. Larger wafers could be used. Approximately 100 dies, each of which may be 1 cm square, can be inscribed on the SOI wafer using photolithography or similar processing. Each of the dies can be patterned into devices, with approximately 100 devices per die using ebeam lithography. In this fashion, thousands of testing devices may be created on one SOI wafer. Devices may be coated with metallic nanostructures such as Ag, Ni, Ge, Zn or others. Different shapes and sizes of metallic structures in the range of tens to hundreds of nanometers may be included on each device. The test platform so created can be mounted on a PCB.

The platform allows for the study, design, testing or optimization of optical, electronic and electrical behavior and properties of micro or nanostructured materials, atomic layer structures and localized surface plasmons. The field of studies and effects addressed by such platforms or devices could further include or relate to light manipulation, photocurrent or photocatalysis reactions, wavelength and wavelength frequency management and localized or surface plasmon resonance in any material or device. Such tests may indicate particle size, shape and impact of various metallic or non-metallic structures on a substrate. Physical properties, characteristics, effects, behavior and operating parameters can be measured. The platform allows for both diagnosis and result determination. A unique and non-obvious feature of the invention is the use of light manipulation and optical behavior of nanostructured materials. The platform is a uniquely scalable nano, micro and macro, measuring device that can be used with a multitude of real-time operating platforms. Those skilled in the art would see such a platform allows for the examination of various substrates at the atomic layer scale. The platform can be used for many applications including determination of photon excitation, photocurrent generation, wavelength, wavelength frequency, wavelength resonance, wavelength resonance frequency, electrical and optical conductivity, transparency, thermal transport, radiation absorption, emission and loss.

In an alternative embodiment of the invention described herein introducing separated or connected discrete metallic particles in enhanced TCO coatings and utilizing light manipulation, photocurrent or photocatalysis reactions, wavelength and wavelength frequency management and localized or surface plasmon resonance can increase electrical conductivity to enable new functions such as efficient heating of the TCO by passing large electrical currents through the material. Applications may include self-cleaning surfaces, use as a combined agent with TiO₂ or other self-cleaning materials, de-fogging or de-icing reflective, opaque or transparent surfaces or substrates.

In a further embodiment of the invention described herein introducing separated or connected discrete metallic particles in enhanced TCO coatings and utilizing light manipulation, photocurrent or photocatalysis reactions, wavelength and wavelength frequency management and localized or surface plasmon resonance can improve optical properties by light trapping, coupling into waveguide modes over a narrow or broad wavelength range or coupling narrow or broad angular ranges. Applications include detectors, solar cells, waveguides, solar steel, solar glass, thermal management and security.

In a further embodiment of the invention introducing separated or connected discrete metallic particles in TCO to form enhanced TCO coatings and utilizing light manipulation, photocurrent or photocatalysis reactions, wavelength and wavelength frequency management and localized or surface plasmon resonance can improve optical properties by efficient out-coupling of light from wave-guided modes or light sources over narrow or broad wavelength or angular ranges. Applications include solid-state lighting, flat-panel displays, or other displays, optoelectronics, video games, computers, televisions, monitors, and similar devices.

In an alternative embodiment of the invention introducing separated or connected discrete metallic particles in enhanced TCO coatings and utilizing light manipulation, photocurrent or photocatalysis reactions, wavelength and wavelength frequency management and localized or surface plasmon resonance can improve optical properties by efficient light reflection from coated surfaces or substrates of any organic or inorganic material including metals, glass, ceramics, plastics, polymers or any other materials listed herein in any combination. Applications include solid-state lighting, displays, optoelectronics, video games, computers, architectural materials, energy efficient glass, metals, textiles and fabrics.

In a further embodiment of the invention introducing separated or connected discrete metallic particles in enhanced TCO coatings and utilizing light manipulation, photocurrent or photocatalysis reactions, wavelength and wavelength frequency management and localized or surface plasmon resonance can improve the optical properties in terms of aesthetic preferences, e.g. producing a desirable color or shade. Introducing high or low index insulating nanostructures can achieve different properties. Insulating nanoparticles can scatter light e.g. for a light trapping or detrapping function. Such particles can reduce the net carrier density and produce a shift in the plasma frequency.

Currently there are a wide variety of different charge extraction schemes utilized in solar cells. Engineered metallic nanostructures, coatings or other forms derived from the invention described herein may be used on any substrate or medium and in conjunction with any type of charge separation and extraction technique, e.g. a cell based on pn-junctions, Schottky barriers, donor/acceptor interfaces, etc. utilizing a wide range of inorganic and organic semiconductors, electron and hole conduction layers, hybrid organic/inorganic cells, cells containing bucky balls, nanotubes, nanowires, indium tin oxide, etc. Pn-junction morphology may include scale, size, separation, stacking density, packing density and vertical, lateral and transverse geometries. This may include surface plasmon-polaritons on extended metal regions, localized surface plasmons on metallic nanostructure, spoof Surface Plasmon-Polaritons (spoof-SPP) in the mid IR and THz regions and/or metamaterials and transformation optics concepts. This may also include structured shapes, spirals, aperiodic structures, concentric circles, bull's eyes, targets etc. Materials per this invention may include nanocrystals/lattices, carbon nanotubes, SWCNT, NWCNT, CNW, SNW, nanowire composites and nanomaterial composites. This invention may allow for the exploitation, enhancement, change or suppression of substrate properties e.g. magnetic, electric, dielectric, conductive etc. Further this invention allows for the engineering of pn-junctions or any other form of charge collection mechanism for improved charge transport and electron-hole pair separation dynamics.

In an exemplary embodiment an enhanced TCO coating could be deposited on or integrated into a substrate used as a building, construction or fabrication material. This could reduce temperature fluctuations internal to the structure or building in which the substrate is incorporated. In a film with a sharp absorption edge, heating of the substrate can result in a strong increase in the thermal emission. The thermal emission of a black body scales with the temperature to the fourth power and the emission of materials with sharp absorption edges can be even more strongly temperature dependent.

In an alternative embodiment an enhanced TCO could be deposited on or integrated into textiles, fabrics, clothing, composite or synthetic materials, protective coverings, camouflage, tents, temporary structures, inflatable balloons, airships, emergency rescue, reconnaissance, ecological, environmental, communications and recreational craft or structures or deployed as cladding material for construction, industrial, aerospace, transportation, military and other uses. Active and passive controls could be used to manage various functions such as temperature fluctuations, thermal emissions and radiation, power generation, heating and cooling, energy efficiency and thermal management. These control features could be combined with hardware and software for smart programmable local or remote addressable operability.

In a further embodiment, a metallo-dielectric coating as described in this invention applied to any substrate exposed to solar or thermal radiation can provide control of absorption through triggered thermal emission utilizing light manipulation, photocurrent or photocatalysis reactions, wavelength and wavelength frequency management and localized or surface plasmon resonance. Coating a surface internal to a building or structure can trigger emission when the temperature of that surface reaches a critical value, which can be engineered through control over the film parameters. Thinner coatings can actively control thermal emission while thicker coatings can be also used to control thermal conductance. The increase or decrease in thermal emission can be used to measure the performance of the coating. Modifying the spectral emissivity of the film can be used to control wavelength and temperature-dependent heat transport.

In a further embodiment enhanced TCO could be incorporated in a solar cell configuration on any substrate. Examples are described of enhanced TCO for solar cells on glass and steel. Glass sheets can be coated with enhanced TCO to enhance an optical, electronic, or thermal property. Optically, the metallic nanoparticles scatter a fraction of the light into waveguided modes of the glass and transport this energy to a solar cell (e.g. pn-junction) on the side of the glass. The low index layer thickness and refractive index is chosen to optimize coupling (and minimize decoupling) of light into the waveguide and finally the solar cell. Light concentration enables the solar cells to operate more efficiently. Electronically, the presence of the high electrical conductivity metals can increase the conductivity of the enhanced TCO and allow for better current extraction. Thermally, the presence of high thermal conductivity metals can be used to increase the thermal transport through such a film. Steel or other metal sheets or foils can be coated with enhanced TCO to enhance an optical, electronic, or thermal property. Electronically, the presence of the high electrical conductivity metals can increase the conductivity of the enhanced TCO and allow for better current extraction. Thermally, the presence of high thermal conductivity metals can be used to increase the thermal transport through such a film. Processing such enhanced metallo-dielectric coatings and thin film solar cells could be achieved on the surface of engineered steel or other metals and composites used in transportation or construction industries. Similar ideas can be applied to a wide range of metallic/non transparent products.

In a further embodiment such coatings or films may employ concepts and metamaterials to enable greater control over the flow of light. Metallo-dielectric TCO coatings consisting of deep subwavelength metallic nanostructures in a dielectric matrix possess an effective index that can be locally engineered through choice and placement of metallic inclusions. These metamaterial coatings can be designed as superior broadband anti-reflection, light scattering and concentration layers which utilize light manipulation, photocurrent or photocatalysis reactions, wavelength and wavelength frequency management and localized or surface plasmon resonance. Coatings can be engineered to produce a desired index variation by altering the metal fraction as a function of distance from the substrate. They can be designed to act as a multilayer antireflective coating or so-called “moth eye” structure exhibiting a substantial reduction in light reflection over single layer antireflection coatings. This structure is highly non-reflective with orderly nanostructured surface variations to allow absorption rather than reflection of incoming light. Such coatings could generate higher efficiencies due to enhanced light concentration and scattering effects. The operation of a metamaterials coating does not rely upon plasmonic effects and could utilize a wide variety of earth abundant metals. In both coatings the metal fraction decreases with increasing distance from the substrate. This results in a graded index coating that minimizes reflections over a broad wavelength range. The presence of nanoscale inclusions in an enhanced TCO also induces beneficial light scattering and concentration effects.

Enhanced TCO coatings on glass, steel or any other substrates utilizing light manipulation, photocurrent or photocatalysis reactions, wavelength and wavelength frequency management and localized or surface plasmon resonance can effectively act as a lens, absorber and/or an antireflective coating comprising one or more layers of dielectric materials including but not limited to: organic, metallic, nonmetallic, metalorganic, inorganic materials, metamaterials, microstructures or nanostructured metallo-dielectric films. Coatings may include structures that incorporate silicon, silica, air, gas, and vacuum-filled inclusions.

It is a feature of this invention that the enhanced TCO coatings described can be processed using all known methods of application in addition to established commercial and noncommercial or specialized deposition techniques. Coating methods may include but are not limited to: chemical deposition in which a fluid precursor undergoes a chemical change at a solid surface leaving a solid layer (e.g. plating, chemical solution deposition, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film or solid (e.g. thermal evaporator, microwave, sputtering, pulsed laser deposition, cathodic arc deposition, dipping, painting, printing, screen or ink jet printing, roll to roll coating, spraying, annealing, lithography and photolithography using flexible or rigid masks, templates, or imprints of any sort); reactive sputtering in which a small amount of non-noble gas such as oxygen or nitrogen is mixed with a plasma-forming gas; molecular beam epitaxy in which slow streams of an element are directed at the substrate so material deposits one atomic layer at a time; and spontaneous or self-assembly induced by various means including nucleation, surface tension, strain, electrical or thermal activity.

A feature of this invention is to enable deposition or application of the coatings on various substrates. Coatings may be incorporated in or deposited on any substrate including semiconductors such as silicon and GaAs, glass, metals, ceramics, ceramic-metal composites, glass-metal-glass combinations, metal-glass-metal combinations, polymers, plastics, self-assembled monolayers, fabrics, organic materials, inorganic materials, fibers, wood, concrete, cement, fabric, textiles, synthetics, skin, hide and other biological materials. Coatings may also be deposited on or incorporated in protective coatings or similar substrate materials.

A feature of this invention is to allow any metallic, ceramic composite, organic, inorganic, nonmetallic, metalorganic, metamaterial, nanostructure, microstructure, nanopatterned structure or nanoengineered material to be included in coatings. Examples include silicon dioxide, titanium dioxide, silver, gold, and other metals or metal oxides. Such materials may be used for local field enhancement, light scattering, concentration, waveguide, modes or paths for combined or redirected photons. Said materials may be used as antennas or receivers to harvest light or thermal energy from solar or other sources. An exemplary embodiment may include structured nanoantennas contained in or deposited on any substrate, material or light-transparent material used to harvest energy from optical, thermal or electromagnetic excitation.

The various features, methods, means or structures of the invention described herein could be expressed in or deposited on any combination of any or all of the following or any other architectures, form factors, materials or combination of materials including:

A metallic

A nonmetallic

An organic

An inorganic

A metal organic

A metal organic compound

An organometallic

A metal oxide

An oxide

A metal oxide film

A metal oxide composite film

A silicon

A silica

A silicate

A ceramic

A composite

A compound

A polymer

A plastic

An organic composite thin film

An organic composite coating

An inorganic composite thin film

An inorganic composite coating

An organic and inorganic composite thin film

An organic and inorganic composite coating

A thin film crystal lattice nanostructure

An active photonic matrix

A flexible multi-dimensional film, screen or membrane

A microprocessor

A MEMS or NEMS device

A microfluidic or nanofluidic chip

A single nanowire, nanotube or nanofiber

A bundle of nanowires, nanotubes or nanofibers

A cluster, array or lattice of nanowires, nanotubes or nanofibers

A single optical fiber

A bundle of optical fibers

A cluster, array or lattice of optical fibers

A cluster, array or lattice of nanoparticles

Designed or shaped single nanoparticles at varying length scales

Nanomolecular structures

Nanowires, dots, rods, particles, tubes, sphere, films or like materials in any combination

Nanoparticles suspended in various liquids or solutions

Nanoparticles in powder form

Nanoparticles in the form of pellets, liquid, gas, plasma or otherwise

Nanostructures, nanoreactors, microstructures, microreactors, macrostructures or other devices

Combinations of nanoparticles or nanostructures in any of the forms described or any other form

Nanopatterned materials

Nanopatterned nanomaterials

Nanopatterned micro materials

Micropatterned metallic materials

Microstructured metallic materials

Metallic micro cavity structures

Metal dielectric material

Metal dielectric metal materials

Autonomous self-assembled or self-assembling structure of any kind

Combination of dielectric metal materials or metal dielectric metal materials

A semiconductor

Semiconductor materials including CMOS, SOI, germanium, quartz, glass, inductive, conductive or insulation materials, integrated circuits, wafers, or microchips

An insulator

A conductor

A paint, coating, powder or film in any form containing any of the materials identified herein or any other materials in any combination

Combinations of nanoparticles or nanostructures in any of the forms described or any other form

All or any of the materials or forms described herein may be designed, used or deployed on or in flexible, elastic, conformable structures. Said structures or surface areas may be expanded or enlarged by the use of advanced non-planar, non-linear geometric and spatial configurations.

In any embodiment or description contained herein the method of enabling the various functions, tasks or features contained in this invention includes performing the operation of some or all of the steps outlined in conjunction with the preferred processes or devices. This description of the operation and steps performed is not intended to be exhaustive or complete or to exclude the performance or operation of any additional steps or the performance or operation of any such steps or the steps in any different sequence or order.

The foregoing means and methods are described as exemplary embodiments of the invention. Those examples are intended to demonstrate that any of the aforementioned steps, processes or devices may be used alone or in conjunction with any other in the sequence described or in any other sequence.

It is also understood that the examples and implementations described herein are for illustrative purposes only and that various modifications or changes in light thereof will be suggested to persons skilled in the art and are to be included within the spirit and purview of this application.

1. A method of engineering enhanced transparent conducting oxides by incorporating discrete metallic particles and structures, nonmetallic, organic and inorganic metamaterials or nanostructures.

2. A method of claim 1 wherein high conductivity metals can be introduced into the TCO in the form of nanoparticles, nanowires, branched nanostructures, or micron scale metallic structures.

3. A method of using enhanced transparent conducting oxides to manipulate optical, thermal, electronic or electrical energy, properties or effects.

4. A method of claim 3 wherein metallic and other nanostructures can be used to perform simultaneous electrical, thermal, and optical functions such as increasing electrical and thermal transport or heating by reason of their superior optical, electrical, electronic and thermal properties.

5. A method of claim 3 wherein discrete metallic nanostructures in the TCO layer optimize the optical, thermal, electronic and electrical behavior and properties of micro or nanostructured materials, atomic layer structures and localized surface plasmons through light manipulation, photocurrent or photocatalysis reactions, wavelength and wavelength frequency management and localized or surface plasmon resonance in any material or device.

6. A method of claim 3 wherein the introduction of separated or connected metallic particles increases electrical conductivity.

7. A method of claim 3 wherein incorporation of sub-wavelength metallic nanostructures can result in the formation of an effective medium with an increased average carrier density, shifting its plasma frequency and changing the wavelength/color where the TCO becomes transparent.

8. A method of claim 3 wherein sub-wavelength particles can be used to control absorption and scattering at desired wavelengths related to or dependent on the localized or surface plasmon resonance of a specific particle.

9. A method of claim 3 wherein particles can be used to engineer various optical effects including absorption, concentration, scattering, wave-guiding, coupling, emission, reflection, light trapping or detrapping, filtering and light induced heating.

10. A method of claim 3 wherein particles of a sufficiently large size are incorporated in an enhanced TCO layer so that it no longer behaves as an effective medium with a higher charge concentration and allows strong reflection at longer wavelengths to be avoided.

11. A method of claim 3 wherein the control of physical features or morphology of particles including size, shape, density, uniformity, conformity, separation, placement and regular, random, aperiodic or periodic distribution can be used to influence increased light manipulation and other effects.

12. A method of claim 3 wherein the different optical properties of connected metal networks and disconnected particles may be optimized for specific functions.

13. A method of claim 3 wherein high or low index insulating nanostructures can reduce the net carrier density and produce a shift in the plasma frequency for improved control of refractive and reflective optical properties or functions.

14. A method of claim 3 wherein the exploitation, enhancement, change or suppression of enhanced properties such as magnetic, electric, dielectric, conductive is enabled on a substrate material.

15. A method of claim 3 wherein the engineering of electrodes, pn-junctions or any other form of charge injection, extraction or collection mechanism can be used to improve charge transport and electron-hole pair separation dynamics.

16. A method of claim 3 wherein a coating could be deposited on or integrated into a substrate used as a building, construction or fabrication material to reduce temperature fluctuations internal or external to the structure or building in which the substrate is incorporated.

17. A method of claim 3 wherein a film engineered to modify spectral emissivity can be used to control wavelength and temperature-dependent heat transport by coating a surface internal or external to a building or structure.

18. A method of claim 3 wherein thinner coatings can control thermal emission while thicker coatings can control thermal conductance.

19. A method of claim 3 wherein glass, steel or other metal sheets or foils can be coated to improve optical, electronic, electrical or thermal properties or functions.

20. A method of engineering enhanced transparent conducting oxides by first the deposition of a first TCO layer, second the deposition or inclusion of metallic or other nanostructures, and third the deposition of a second TCO layer.

21. A method of claim 20 wherein the thickness and composition of the first TCO layer could be the same as or different from the thickness and composition of the second TCO layer.

22. A method of claim 20 wherein the metallic nanostructures could include a variety of metals or other materials in a plurality of forms and structures.

23. A method of claim 20 wherein a test platform may be used in the study, design, testing or optimization of thin films, semiconductors, solar cells or similar devices, structures and materials.

24. A method of claim 20 wherein enhanced TCO can be processed using all known methods of application in addition to established commercial and noncommercial or specialized deposition techniques which may include but are not limited to: chemical deposition in which a fluid precursor undergoes a chemical change at a solid surface leaving a solid layer (e.g. plating, chemical solution deposition, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film or solid (e.g. thermal evaporator, microwave, sputtering, pulsed laser deposition, cathodic arc deposition, dipping, painting, printing, screen or ink jet printing, spraying, roll to roll coating, annealing, lithography and photolithography using flexible or rigid masks, templates, or imprints of any sort); reactive sputtering in which a small amount of non-noble gas such as oxygen or nitrogen is mixed with a plasma-forming gas; molecular beam epitaxy in which slow streams of an element are directed at the substrate so material deposits one atomic layer at a time; and spontaneous or self-assembly induced by various means including nucleation, surface tension, strain, electrical or thermal activity.

25. A method of claim 20 wherein the various features, methods, means or structures of the invention described herein could be expressed in or deposited on any combination of any or all of the following or any other architectures, form factors, materials or combination of materials including: metallic, nonmetallic, organic, inorganic, metal organic, organometallic, metal oxide, metal oxides, oxide, oxides, silicon, silica, silicate, ceramic, composite, compound, compound substances, polymer, plastic, organic composite thin film, organic composite coating, inorganic composite thin film, inorganic composite coating, organic and inorganic composite thin film, organic and inorganic composite coating, thin film crystal lattice nanostructure, active photonic matrix, flexible multi-dimensional film, screen or membrane, microprocessor, MEMS or NEMS device, semiconductors, insulator, conductor, semiconductor materials including CMOS, SOI, germanium, quartz, glass, inductive, conductive or insulation materials, integrated circuits, wafers, microchips, microfluidic or nanofluidic chips, single nanowire, nanotube or nanofiber, bundle of nanowires, nanotubes or nanofibers, cluster, array or lattice of nanowires, nanotubes or nanofibers, single optical fiber, bundle of optical fibers, cluster, array or lattice of optical fibers, cluster, array or lattice of nanoparticles, designed or shaped single nanoparticles at varying length scales, nanomolecular structures, nanowires, dots, rods, particles, tubes, spheres, films or like materials in any combination, nanoparticles suspended in various liquids or solutions, nanoparticles in powder form, nanoparticles in the form of pellets, liquid, gas, plasma or otherwise, nanostructures, nanoreactors, microstructures, microreactors, macrostructures or other devices, nanoparticles or nanostructures in any of the forms described or any other form, nanopatterned materials, nanopatterned nanomaterials, nanopatterned micro materials, micropatterned metallic materials, microstructured metallic materials, metallic micro cavity structures, metal dielectric materials, metal dielectric metal materials, an anode, a cathode, a self-assembled or self-assembling structure of any kind, a paint, coating, powder or film in any form containing any of the materials identified herein or any other materials.
